(19) United States
(12) Patent Application Publication
(10) Pub. No.: US 2025/0361607 A1
(43) Pub. Date: Nov. 27, 2025

(54) METHOD FOR SYNTHESIZING CRYSTALLINE LAYERS OF MANGANESE OXIDES, IN PARTICULAR FOR RECHARGEABLE BATTERIES

(71) Applicants: Centre National de la Recherche Scientifique, PARIS (FR); UNIVERSITE PARIS 13 PARIS-NORD VILLETANEUSE, Villetaneuse (FR)

(72) Inventors: Mehrdad NIKRAVECH, Saint-Pryvé-Saint-Mesmin (FR); Lounis Hakim BEKKAR, Saint-Denis (FR)

(21) Appl. No.: 19/124,661

(22) PCT Filed: Oct. 26, 2023
(86) PCT No.: PCT/EP2023/079968

§ 371 Date: Apr. 25, 2025

(30) Foreign Application Priority Data
Oct. 26, 2022 (FR) FR2211169
Feb. 24, 2023 (EP) 23020093.3

(51) Int. Cl. C23C 16/40; C23C 16/455; H01M 4/04; H01M 4/50

(52) U.S. Cl. CPC C23C 16/40; C23C 16/455; H01M 4/0428; H01M 4/502

(57) ABSTRACT

A method for synthesizing at least one crystalline layer of manganese oxides that can contain zinc, of formula ZnₓMn_{y}O_{z}, where x is greater than or equal to 0, y is greater than 0, and z is greater than 0, the method being implemented in a chamber of a low-pressure plasma reactor, kept between 10 Pa and 10⁵ Pa, the method comprising forming a plasma discharge from a plasma-generating gas; adding, in the form of a nebulizate, a predetermined amount of a manganese precursor; adding a reactive gas so as to create oxygen vacancy defects in the layer of manganese oxides, and/or so as to maintain a controlled redox environment; synthesizing and depositing, on a substrate, the at least one crystalline layer of manganese oxides that can contain zinc, these operations being carried out at a substrate temperature of 400° C. or less, advantageously 200° C. or less.

### PRIOR ART—TECHNICAL PROBLEM

Lithium-ion batteries (LIBs) dominate the electricity storage market. However, as available lithium resources dry up and the price of lithium rises, there is a particular need for alternative solutions offering similar performance. Zinc is considered an alternative material of similar performance to lithium. A number of recent studies have shown that materials based on spinel ZnMn₂O₄ as a cathode material have characteristics that tend to approach those of lithium-based batteries in terms of cyclability and electrochemical properties (mass or volume capacity, etc., e.g. Cai et al 2022).

There are, however, difficulties to be overcome before zinc can replace lithium to produce zinc-ion batteries (ZIB). One of the major challenges is to produce layers of ZnxMnyOz oxide with controlled stoichiometry, allowing oxygen vacancies to be created at a low temperature while preserving its spinel crystallographic structure. Conventional production processes described in the literature, such as solvothermal, colloidal, sol-gel or emulsion synthesis, all require a series of multiple, lengthy and complex steps and, at the end of the production process, high annealing temperatures (500° C. or even more, for several hours), which consume a great deal of energy and time. In addition, the powder resulting from these processes, which comprises the crystals of manganese oxides, requires the use of a binder and/or glue to apply it an electrode carrier substrate surface (known as the current collector) and/or a protective coating, which can affect the electrochemical performance of the ZIB.

There are ZIBs whose cathode materials are formed solely by manganese oxides (without zinc oxide); a drawback of these ZIBs is the instability of these cathodes related to the dissolution of MnO₂ in the electrolyte, which prejudices the number of charge-discharge cycles possible for these batteries. Carbon materials such as graphene mixed with the cathode material or the application of a protective graphene layer to the electrodes have been used to overcome this drawback (Wu et al., 2018). However, such materials are expensive, can reduce electrochemical performance and are therefore incompatible with the production of high-performance ZIBs at reasonable cost. Application WO 2020/176787 describes a cathode comprising a layer of manganese oxides for ZIBs, on which a protective coating, based in particular on oxides which are not zinc oxides, is deposited. This coating is designed to protect the manganese electrode from dissolution.

In view of the promising performance of manganese oxides, the growing need for electrical energy storage solutions and the need to save scarce environmental resources, there is a need to find a simple and fast method for producing stable, high-performance ZIB battery cathodes to facilitate the development of manganese oxide-based ZIB batteries. The method by Mollar et al. (2009) is a liquid-phase electrochemical deposition technique and its authors target applications in magnetic semiconductors; the method by Mollar et al. involves doping the layers with Mn. Mollar et al. mentions nothing regarding any electrochemical performance.

In response to the above-mentioned need, the inventors have developed a low-pressure, low-temperature plasma-based method that allows the deposition of layer of manganese oxides, which can comprise zinc, of formula Znx Mny Oz (x greater than or equal to 0, y and z greater than 0) in a single step, at a temperature not exceeding 200° C. The layers deposited directly on the substrate, without the addition of binder(s) or carbon other than that produced in situ, and resulting from the method of the invention have electrochemical properties (cyclic voltammetry, charge capacity measurement) that meet those required to form rechargeable batteries and allow a satisfactory number of charge/discharge cycles, similar to those of materials obtained via techniques of the prior art which involve an annealing step. This method also allows the stoichiometry of the layers produced, and thus their electrochemical performance, to be controlled.

### SUMMARY OF THE INVENTION

Thus, according to a first aspect, the invention relates to a method for synthesizing at least one crystalline layer of manganese oxides that can contain zinc, of formula ZnxMnyOz, where x is greater than or equal to 0, y is greater than 0, and z is greater than 0,
said method for synthesizing at least one crystalline layer of manganese oxides that can contain zinc being implemented in a chamber of a low-pressure plasma reactor, said pressure in said chamber being kept between 10 Pa and 10⁵, advantageously between 10 Pa and 100 Pa,
said method for synthesizing at least one crystalline layer of manganese oxides comprising:
   forming a plasma discharge from a plasma-generating gas,
   at least one operation of adding, to the chamber of the reactor and in the form of a nebulizate, a predetermined amount of at least one manganese precursor and, optionally, a predetermined amount of at least one additional precursor such as zinc, simultaneously or consecutively, the precursors being dissolved in a solvent so as to be added to the plasma reactor in the form of a nebulizate,
   at least one operation of adding, to the chamber of the reactor, a reactive gas which mixes with the precursor so as to create oxygen vacancy defects in the layer of manganese oxides, and/or so as to maintain a controlled redox environment in the chamber of the reactor,
   the precursors being dissolved in a solvent so as to be added to the plasma reactor in the form of a nebulizate,
   synthesizing and depositing, on a substrate, the at least one crystalline layer of manganese oxides that can contain zinc, of formula ZnₓMn_{y}O_{z}, said synthesizing and depositing (140) operations being carried out at a substrate temperature of 400° C. or less, advantageously 200° C. or less.

Unlike the methods of the prior art, the method according to the invention allows said layer to be deposited directly on, for example, a conductive substrate. It also allows the composition of these layers of manganese oxides of composition ZnₓMn_{y}O_{z} to be controlled and thereby optimize the electrochemical properties and durability thereof.

According to other, optional features of the method, included alone or in combination:
to create oxygen vacancy defects in the layer of manganese oxides, at least one carbon precursor such as acetates or acetylacetonates is added,
to create oxygen vacancy defects in the layer of manganese oxides, a predetermined amount of at least one reducing gas is added,
the operations of synthesizing and depositing the layer of ZnₓMn_{y}O_{z} are carried out at a substrate temperature of 100° C. or less, advantageously less than 50° C. The method thus allows deposition on heat-sensitive substrates, thereby broadening the range of possible substrates, particularly for electrochemical applications,
in the step of adding the precursors, the ratio of amount of manganese precursor to amount of zinc precursor is greater than or equal to 2, or even greater than or equal to 10,
the step of adding manganese and optionally zinc precursors further comprises adding a precursor of a doping element comprising salts of: copper and/or vanadium, said precursors being solid under normal temperature and pressure conditions, and added to the reactor dissolved in a solvent in the form of a nebulizate,
the precursors of Mn, optionally of Zn, and of optional doping elements are in the form of nitrate, chloride, acetate, acetylacetonate, acetonate or any other salts, and in that the precursors are soluble in a solvent such as water, ethanol, methanol, propanol, hexane, heptane or octane.
the method (100) is carried out without a step of annealing the at least one crystalline layer of manganese oxides that can contain zinc of composition ZnₓMn_{y}O_{z}, dispensing with such a step is particularly advantageous both in terms of energy savings and process speed, since such steps can last several hours and require subsequent treatments depending on the chosen applications, particularly for electrode production (for example, reducing to powder then applying with a binder),
the reactive gas or the plasma-generating gas comprises oxygen,
the carrier gas is selected, for example, from the following list: argon, helium, krypton.
the reactive or plasma-generating gas comprises reducing molecules selected from a hydrocarbon such as an alcohol or an aliphatic hydrocarbon.
the reducing gas is selected from carbon monoxide, carbon dioxide, CH₄, H₂, NH₃, methanol, propanol, methane, ethane, propane, or any other hydrocarbon capable of reacting with oxygen in plasma, or mixtures thereof,
the reactive or plasmagenic gas composition is selected so as to allow the formation of graphene and/or oxygraphene in the at least one crystalline layer of manganese,
the method is carried out in a single step, for example lasting less than 1 hour,
the plasma is produced by an alternating electric generator, by inductive or capacitive radiofrequency, or an ECR (electron cyclotron resonance) microwave source, or by applying a direct voltage,
in this method:
   the nebulizates comprising the precursors are carried by the reactive gases or a carrier gas, and in the case of a carrier gas, this is also mixed with the reactive gases;
   the reactive gases and the nebulizates are added simultaneously or consecutively through one or more inlet ends of the reactor, and react together in the plasma,
   the vapor or gaseous by-products exiting via one or more outlet ends are drawn off by a pump coupled to the reactor, and/or
   the substrate is placed in the reactor between one or more inlet ends and one or more outlet ends of the reactor and is thus exposed to the flow of gases and,
in this method:
   the reactive gas or the plasma-generating gas contains oxygen;
   the carrier gas is selected, for example, from the following list: argon, helium, krypton.

Thus, depending on the composition of the reducing gas, the method according to the invention can allow a layer of the following composition to be obtained:
ZnxMnyOz, where x and z represent stoichiometric coefficients greater than 0, and y is greater than or equal to 1, and/or
MnyOz, where y is greater than or equal to 1 and z represents stoichiometric coefficients greater than 0.

More particularly, when the precursor mixture contains a manganese salt and a zinc salt, and the percentage of O₂ in the chamber of the reactor:
is equal to 0%, a crystalline layer of manganese oxides only with the following oxide, Mn_{y}O_{z} (where x=0, y is greater than or equal to 1 and z is greater than zero), is obtained by applying the method of the invention,
is greater than 0% and less than 10%, a crystalline layer of manganese oxides comprising the following oxides is obtained by applying the method of the invention: ZnₓMn_{y}O_{z} (where x is greater than 0, y is greater than or equal to 1 and z is greater than zero), Mn_{y}O_{z} (where y is greater than or equal to 1 and z is greater than zero),
is greater than 17%, a crystalline layer of manganese oxides of composition ZnxMnyOz is obtained by applying the method of the invention.

In one particular embodiment, said method allows at least one crystalline layer of manganese and zinc oxides of a composition ZnxMnyOz to be synthesized, where x, y and z represent stoichiometric coefficients greater than 0,
said method for synthesizing at least one crystalline layer of manganese and zinc oxides of composition ZnₓMn_{y}O_{z} being implemented in a chamber of a low-pressure plasma reactor, said pressure in said chamber being kept between 10 Pa and 10⁵, advantageously between 50 Pa and 100 Pa,
said method for synthesizing at least one crystalline layer of manganese and zinc oxides of composition ZnₓMn_{y}O_{z} comprising:
   forming a plasma discharge from a plasma-generating gas,
   at least one operation of adding, to the chamber of the reactor, a reactive gas which comprises a predetermined amount of:
      at least one reducing gas or
      at least one oxidizing gas
so as to maintain a controlled redox environment in the chamber of the reactor,
   adding, in the form of a nebulizate and/or vapor, a predetermined amount of manganese precursors and a predetermined amount of zinc precursors, simultaneously or consecutively,
   synthesizing and depositing, on a substrate, the layer of ZnₓMn_{y}O_{z} at a substrate temperature of 400° C. or less, advantageously 200° C. or less.

In one even more particular embodiment, said method allows at least one crystalline layer of manganese and zinc oxides of a composition ZnxMnyOz to be synthesized, where x, y and z represent stoichiometric coefficients greater than 0, or equal to 0 for one of the coefficients, with the other coefficients greater than 0,
said method (100) for synthesizing at least one crystalline layer of combined manganese and zinc oxides of composition ZnₓMn_{y}O_{z} being implemented in a chamber of a low-pressure plasma reactor, said pressure in said chamber being kept between 10 Pa and 10⁵, advantageously between 10 Pa and 100 Pa,
said method for synthesizing at least one crystalline layer of manganese and zinc oxides of composition ZnₓMn_{y}O_{z} comprising:
   forming a plasma discharge (110) from a plasma-generating gas,
   at least one operation (120) of adding, to the chamber of the reactor, a reactive gas which comprises a predetermined amount of:
      at least one reducing gas or
      at least one oxidizing gas
so as to maintain a controlled redox environment in the chamber of the reactor,
   adding (130), in the form of a nebulizate and/or vapor, a predetermined amount of manganese precursors and a predetermined amount of zinc precursors, simultaneously or consecutively,
   synthesizing and depositing (140), on a substrate, the layer of ZnₓMn_{y}O_{z} at a substrate temperature of 400° C. or less, advantageously 200° C. or less.

According to a second aspect, the invention relates to an assembly comprising at least one crystalline layer of manganese oxides that can contain zinc of composition ZnxMnyOz, where x is greater than or equal to 0, y is greater than or equal to 1 and z is greater than 0, obtained according to the method according to the first aspect of the invention, said layer of manganese oxides having a thickness of the order of nanometers to a thickness of the order of micrometers. In particular, these layers exhibit oxygen vacancies in controllable proportions, and are therefore of particular interest for electrochemical applications. Moreover, such thicknesses are particularly advantageous for applications such as rechargeable cells or batteries.

According to other optional features of said assembly comprising at least one crystalline layer of manganese oxides that can contain zinc, alone or in combination:
the layer of manganese oxides ZnₓMn_{y}O_{z} comprises graphene and/or oxygraphene,
the ratio of amount of Zn/amount of Mn is less than 0.5, preferably less than 0.1 and advantageously less than 0.05,
the manganese oxides of the at least one crystalline layer of manganese oxides are of formula Mn_{y}O_{z}, where y represents stoichiometric coefficients greater than or equal to 1, z represents stoichiometric coefficients greater than 0,
the manganese oxides of the at least one crystalline layer of manganese oxides are of formula:
   ZnₓMn_{y}O_{z}, where x and z represent stoichiometric coefficients greater than 0, and y greater than or equal to 1 and
   Mn_{y}O_{z}, where y represents stoichiometric coefficients greater than or equal to 1 and z represents stoichiometric coefficients greater than 0,
said assembly comprises
   a crystalline layer composed solely of manganese oxide of formula MnO,
   a crystalline layer of manganese oxides wherein the manganese oxides of formula ZnMn₂O₄ and MnO, or
   a layer with only the following oxide ZnMn₂O₄.

According to a third aspect, the invention therefore relates to a cathode for a zinc-ion battery (ZIB) comprising, on a conductive substrate, at least one layer of manganese oxides that can contain zinc, of formula ZnxMnyOz, where x is equal to or greater than 0, and y and z are greater than 0, resulting from the method according to the first aspect.

According to other, optional features of this cathode according to this third aspect, included alone or in combination:
the substrate on which said at least one layer is deposited is a conductive metal, for example selected from the following list: Al, Cu, Pt, Ag, steel, stainless steel or one of the alloys thereof,
x=1, y=2 and z=4. As demonstrated in the experimental section, such a cathode is efficient,
the substrate is a conductive metal, for example selected from the following list: Al, Cu, Pt, Ag, steel, stainless steel or an alloy of these metals,
the substrate is a conductive polymer or a polymer coated with a layer of conductive material, in the form of sheets or plates,
said cathode not comprising a protective layer, covering said layer of manganese oxides, and wherein said at least one layer of manganese oxides does not comprise a glue or binder. These features contribute to the electrochemical efficiency of the cathode according to the invention and optimize its service life.

According to a fourth aspect, the invention also relates to a Zn-ion battery (ZIB) comprising:
at least one cathode according to the third aspect of the invention,
at least one anode comprising zinc, and
at least one electrolyte of at least one manganese salt.

As mentioned, such batteries, which comprise at least one cathode according to the invention, are valid alternatives to LiBs, allowing scarce resources to be saved, with suitable electrochemical performance.

### FIGURES

Other objectives, features and advantages will become apparent from the following detailed description with reference to the drawings provided for illustrative and non-limiting purposes, wherein:

FIG. 1: Method according to one embodiment of the invention.

FIG. 2A: Raman spectra of ZnMn₂O₄ produced at low temperature (200° C.) with or without annealing at 500° C. for 4 hours.

FIG. 2B: X-ray diffraction pattern of tetragonal ZnMn₂O₄ layers without annealing, showing the crystal structure of the layers produced at 200° C., and after annealing at 500° C. for 4 hours. The ZnMn₂O₄ reference is taken from the CIF database mp-1875.

FIG. 3A: cyclic voltammetry curves for crystalline layers of ZnMn₂O₄ manganese oxides obtained according to the method of the invention. The number of charge-discharge cycles is indicated.

FIG. 3B: cyclic voltammetry curves for crystalline layers of ZnMn₂O₄ manganese oxides obtained according to a method of the prior art (Sinian Yang et al. (2019)). The data show electrochemical properties similar to those in FIG. 3A. The number of charge-discharge cycles is indicated.

FIG. 4: a depiction of the device used to implement the method according to the invention.

FIG. 5: result of the Raman spectroscopic analysis of a layer of ZnMnO obtained according to the method of the invention. Depending on the amount of oxygen present in the reactive mixture, and in the presence of the element carbon, the presence of graphene or oxygraphene sheets may be observed, shown by the G (G) and D (D) bands, which are specific signatures for graphene and oxygraphene. The specific signatures for ZnxMnyOz on the one hand and for graphene and oxygraphene on the other hand are in boxes. It is observed that the more oxygen there is in the reaction mixture, the fewer graphene layers are formed: At 70 mL/min oxygen, no graphene layer is detected in the layer of ZnMnO.

FIG. 6: Electron microscopy image of a zinc-doped layer of manganese oxides according to the invention deposited on a silicon substrate and obtained according to the method of the invention: under the conditions tested, a layer with a thickness of 1.4 μM is obtained.

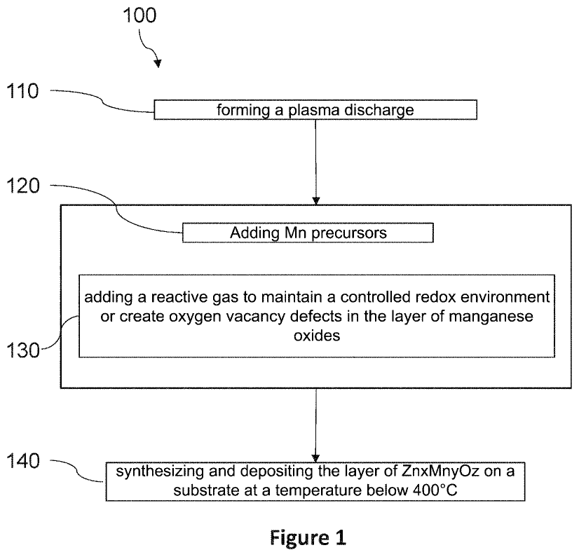

### DETAILED DESCRIPTION OF EMBODIMENTS

A first subject of the invention therefore relates to a plasma method for synthesizing at least one crystalline layer of manganese oxides. Advantageously, the method developed makes it possible to control the stoichiometry, in particular the oxygen stoichiometry, of a crystalline layer of manganese oxides of formula Znx Mny Oz, which makes it possible to vary and optimize the electrochemical properties and doping possibilities of the layers. This method also has the particularity of being implemented in a low-pressure plasma reactor at low temperatures, which is particularly advantageous from the point of view of the energy cost of synthesizing the crystalline layers. This also allows implementation on heat-sensitive substrates. The method of the invention also makes it possible to favor the doping of the layers of a crystalline layer of manganese oxides of formula Znx Mny Oz with elements such as N, Cu, Ag, V, etc. from the periodic table.

For the purposes of the invention, a crystalline layer of manganese oxides of formula Znₓ Mn_{y} O_{z} is understood as a crystalline layer in which the elements Zn, Mn and O are covalently and/or ionically bonded to one another and/or are interstitially present in the crystal lattice. Thus, a layer of manganese oxides produced according to the method of the invention may comprise oxides of manganese and zinc and/or another cation, depending on the reaction mixture produced in the reactor, one embodiment of which is described below.

Thus, this first subject of the invention relates to a method for synthesizing at least one crystalline layer of manganese oxides of composition ZnxMnyOz, where x is greater than or equal to 0, y is greater than 0, and z is greater than 0,
said method for synthesizing at least one crystalline layer of manganese oxides of composition ZnₓMn_{y}O_{z} being implemented in a chamber of a low-pressure plasma reactor, said pressure in said chamber being kept between 10 Pa and 10⁵, 25 Pa et 10⁴ Pa, advantageously between 50 Pa and 100 Pa,
said method for synthesizing at least one crystalline layer of manganese oxides of composition ZnₓMn_{y}O_{z} comprising:
   forming a plasma discharge from a plasma-generating gas,
   at least one operation of adding, in the form of a nebulizate, a predetermined amount of manganese precursors and optionally a predetermined amount of zinc precursors, simultaneously or consecutively,
the precursors being dissolved in a solvent so as to be added to the plasma reactor in the form of a nebulizate,
   at least one operation of adding, to the chamber of the reactor, a reactive gas which mixes with the precursor so as to create oxygen vacancy defects in the layer of manganese oxides, and/or so as to maintain a controlled redox environment in the chamber of the reactor,
   synthesizing and depositing, on a substrate, the at least one layer of manganese oxides of formula ZnₓMnyO_{z}, said synthesizing and depositing operations being able to be carried out at a substrate temperature of 400° C. or less, advantageously 200° C. or less.

Of course, as long as the reactive gas and the one or more precursors mix adequately in the reactor to allow the reaction and deposition of the layer of manganese oxides on the substrate in the plasma reactor, the order in which the reactive gas on the one hand, and the one or more precursors on the other hand, are added is of no consequence. In one embodiment, they may be added concomitantly.

In one particular embodiment, the synthesis method according to the invention is a method for synthesizing at least one crystalline layer of manganese oxides of formula ZnxMnyOz, where x is greater than or equal to 0, y is greater than or equal to 1, and z is greater than 0.

In one particular embodiment, the synthesis method according to the invention is a method for synthesizing at least one crystalline layer of manganese oxides of formula ZnxMnyOz, where x is greater than 0, y is greater than 0, and z is greater than 0.

In another particular embodiment, the synthesis method according to the invention is a method for synthesizing at least one crystalline layer of manganese oxides of formula ZnxMnyOz, where x is greater than 0, y is greater than or equal to 1, and z is greater than 0.

In one embodiment, said at least one layer of manganese oxides comprises manganese oxides of formula ZnxMnyOz, where x=1, y=2 and z=4.

In one embodiment, the synthesis method according to the invention is a method for synthesizing at least one crystalline layer of manganese oxides comprising manganese oxides of formula ZnxMnyOz, where x is greater than 0, y is greater than 0, and z is greater than 0, and/or MnyOz (x then being equal to 0 and Zn therefore absent) where y is greater than 0, and z is greater than 0.

In another particular embodiment, the synthesis method according to the invention is a method for synthesizing at least one crystalline layer of manganese oxides of formula ZnxMnyOz, where x is 0, y is greater than 0, and z is greater than 0. The at least one crystalline layer of manganese oxides therefore has the formula MnyOz, where y is greater than 0 and z is greater than 0.

In another particular embodiment, the synthesis method according to the invention is a method for synthesizing at least one crystalline layer of manganese oxides of formula ZnxMnyOz, where x is 0, y is greater than or equal to 1, and z is greater than 0. The at least one crystalline layer of manganese oxides therefore has the formula MnyOz, where y is greater than or equal to 1, and z is greater than 0.

It is understood that the predetermined amounts of precursors are defined so as to make it possible to obtain said crystalline layer of a composition in accordance with the above-mentioned stoichiometric coefficients.

The plasma-generating gas is advantageously selected from argon, helium, neon, xenon, dihydrogen or mixtures thereof. It can be mixed with at least one other gas such as N₂, CO, CO₂, CH₄, H₂, Cl₂, F₂, H₂O or other gaseous hydrocarbons (such as C₂H₂, C₂H₄, C₂H₆, or organic vapors) or mixtures thereof. In the method according to this first subject of the invention, the plasma can be generated by an alternating electric generator, by inductive or capacitive radiofrequency, or an ECR (electron cyclotron resonance) microwave source, or by applying a direct voltage, according to means known to a person skilled in the art.

The reactive gas, comprising a predetermined amount of at least one reducing gas, is selected so as to maintain a controlled redox environment in the chamber of the reactor and thereby control the oxygen stoichiometry of the oxide layers and, consequently, modulate the presence, in said at least one crystalline layer, of oxygen vacancies which are advantageous for the electrochemical applications of these layers. One of the effects of creating vacancies is in particular that of reducing the loss of capacity of the material as observed in conventional materials during charge-discharge cycles.

The molar ratio of oxygen to reducing gas in the chamber of the reactor advantageously varies between 0% and 30%, varying this ratio making it possible to vary the z coefficient of the at least one ZnₓMn_{y}O_{z} crystalline layer according to the desired electrochemical properties. For example, the higher the oxygen gas/plasma gas ratio or the higher the reducing gas/plasma gas ratio, the lower the z value and the more gaps in the crystal structure of the layer. Advantageously, this ratio is between 0% and 20%, and even more advantageously between 0% and 10%.

Any reducing gas that can react with oxygen in plasma can be used in the method according to the first subject of the invention. In one particular embodiment, the reducing gas can comprise carbon monoxide, carbon dioxide, CH₄, H₂, NH₃, methane, ethane, propane, methanol, propanol or any other hydrocarbon, such as an aliphatic hydrocarbon or suitable alcohol or mixtures thereof.

Oxidizing gases can be used; these can comprise molecular oxygen, ozone, water vapor or mixtures thereof. These gases supply molecular oxygen and hydroxyl radicals to the plasma reactive medium.

In particular, the Zn/Mn molar ratio in the mixture of precursors makes it possible in particular to control the x and y coefficients of the at least one ZnxMnyOz crystalline layer resulting from the implementation of the method. It can be less than or equal to 0.5, preferably less than or equal to 0.1, and advantageously less than 0.05.

The inventors have also discovered that the presence of reducing gas in the mixture of precursors contributes to the decrease of Zn in the crystalline layer: For reducing gas/plasma gas ratios greater than 1, the value of x decreases.

In the method according to the invention, the one or more mixtures of precursors are advantageously added in the form of a one or more nebulizates (i.e. a spray) produced, for example, using ultrasound or any other suitable means such as electrospray or injection needles. As commonly accepted and according to the above definition, a nebulizate is defined as an aggregation or cloud of suspended liquid droplets; the droplets may be microdroplets. This adding operation can be continuous or pulsed.

In the method according to the present invention, the precursors are dissolved in a solvent to be added to the plasma reactor in liquid form. These can be solid salts in their natural state, at atmospheric pressure and ambient temperature, with very high boiling points; they are dissolved in a solvent and added to the plasma reactor in liquid form. These precursors are salts of the metals Mn, Cu, Zn and V, which are solid at room temperature and atmospheric pressure. The device for implementing the method according to invention allows the formation of a fine mist of droplets or even microdroplets which is added to the chamber by means of a carrier gas (selected, for example, from argon, helium, krypton; advantageously argon).

The manganese and optionally zinc precursors can be of any composition suitable for plasma crystalline layer synthesis and the method according to the first subject of the invention. More particularly, in one particular embodiment of this first subject, the precursors are in the form of nitrate, chloride, acetate, acetylacetonate, acetonate or any other salts of zinc or manganese. Even more particularly, to create oxygen vacancy defects in the layer of manganese oxides, a precursor in the form of a carbon precursor, such as an acetate or acetylacetonate, is added.

The precursors are soluble in a solvent such as water, ethanol, methanol, propanol, hexane, heptane or octane.

The method according to the first subject of the invention allows the synthesis of said at least one crystalline layer and deposition on the substrate in a single step, which is particularly advantageous in terms of yield and resource savings. In particular, the crystalline layer formation in the method according to invention does not require an annealing step, which is characterized by exposure of the mixture to high temperatures (usually between 500° C. and 800° C., or even higher) for a period of several hours. This step makes these methods particularly time-consuming and energy-intensive, and they do not allow direct deposition of a crystalline layer directly on a substrate which cannot withstand exposure to such high temperatures. In addition, the absence of further processing such as grinding and then application as a paste with a binder, for example in the case of application to a conductive substrate, avoids any negative effect of these on the electrochemical properties of the manganese oxide crystals and loss of material. The experimental data below confirm the crystalline structure of the layers produced according to the method that is the first subject of the invention.

This method is particularly suited to the generation of material comprising multiple crystalline layers i, which may be the same or different, of composition ZnₓᵢMn_{yi}O_{zi}, where xi, yi and zi represent stoichiometric coefficients of each crystalline layer of manganese oxides i. In one particular embodiment, different layers i of composition ZnₓᵢMn_{yi}O_{zi} can be obtained by varying, for the different adding operations: the characteristics of the reactive gas (for example, the oxygen gas/reducing gas ratio and/or the composition and nature of the reducing gas) and/or the characteristics of the mixture of manganese precursors optionally comprising zinc precursors (for example, the ratio of the precursors and/or the composition of the manganese precursor). The series of crystalline layers also makes it possible to control and optimize the thickness of the deposited crystalline material, which comprises layers of identical or different composition and/or stoichiometry.

In one particular embodiment of the method constituting the first subject of the invention, at least one doping element is added the at least one precursor-adding step. The presence of vacancies in the crystalline layer makes the layers obtained by this method particularly suitable for doping. This doping element may be any element from the periodic table, in particular, but not limited to, N, Cu, Ag or V. Even more particularly, this at least one doping element is selected from nitrate, sulfate, chloride, acetate, acetylacetonate, acetonate, and/or organometallic compounds of metals such as copper or aluminum. The precursor of the at least one doping element can be added to the mixture of Mn precursors optionally comprising Zn. In one particular embodiment, in the event of incompatibility, for example, between the at least one precursor of the doping element and the at least one manganese precursor, the at least one precursor of the doping element can be added in the form of a nebulizate or spray via a route parallel to the route of the main mixture of precursors. These doping elements are solid under normal temperature and pressure conditions (i.e. room temperature and pressure). To allow them to be used in the method, these elements are dissolved in a solvent and then added to the reactor in the form of a nebulizate (i.e. in the form of a cloud of droplets or even a cloud of microdroplets) at the low temperatures described.

This method therefore allows crystalline layers with controlled stoichiometry and/or improved and/or controlled electrochemical properties to be generated quickly and easily. In one embodiment, the method according to the invention is a method for synthesizing at least one crystalline layer (and depositing it on the substrate) in a single step. In one embodiment, the method is a method for synthesizing at least one crystalline layer (and depositing it on the substrate) in a single step. With a duration of less than 5 hours, 4 hours, 3 hours, 2 hours or even less than 1 hour. In one particular embodiment, the method for synthesizing at least one crystalline layer (and depositing it on the substrate) in a single step advantageously lasts less than an hour and varies depending on the desired thickness of the crystalline layer. In any event, this time is much shorter than that of conventional synthesis methods, which generally require a large number of lengthy steps lasting up to several days.

In the method according to the invention, the deposition time is variable. Advantageously, it can be modified depending on the desired thickness of the crystalline layer. The method allows deposition speeds of at least 0.1 μm per minute, advantageously higher than 0.2 μm per minute, 0.3 μm per minute, 0.4 μm per minute, 0.5 μm per minute or even higher. This means the method can be completed quickly, in an hour or less. It can last longer if a thicker layer is desired.

In addition to the lower temperature in the chamber, the method according to this first subject of the invention allows deposition of the at least one crystalline layer on a substrate kept at a particularly low temperature. Deposition at low substrate temperature is particularly advantageous, as it allows deposition on heat-sensitive substrates that degrade or denature at the high temperatures of conventional methods. In one particular embodiment of this first subject, deposition takes place at a substrate temperature of less than 100° C., advantageously less than 50° C., even more advantageously less than 30° C.

In one particular embodiment, the substrate is a conductive substrate. This conductive substrate may be of any type, provided it is suitable for the plasma synthesis method of the invention. It may be, for example, a metal or conductive polymer substrate, or comprise a metalized layer. In one even more particular embodiment, the conductive substrate comprises a conductive metal selected from Al, Cu, Pt, Ag, alloys such as steel, stainless steel or an alloy thereof. Deposition on such conductive substrates makes the crystalline layers produced by the method of the invention particularly suitable for use in the field of electrochemistry, and in particular, but without limitation, in rechargeable batteries or cells. The method is suitable for depositing crystalline layers of manganese oxides, of formula ZnxMnyOz, as described above on substrates of any shape and size, which can subsequently be used in turn on any substrate such as a polymer, fabrics, leather, organic materials, etc.

A second subject of the invention relates to a crystalline layer of manganese oxides of composition ZnₓMn_{y}O_{z}, x, y and z being stoichiometric coefficients where x is greater than or equal to 0, and y and z represent stoichiometric coefficients greater than 0, obtained according to the first subject of the invention, or any one of its particular embodiments or combinations thereof. In one particular embodiment, x is greater than or equal to 0, y is greater than or equal to 1, and z is greater than 0. In another embodiment, x is greater than 0, y is greater than or equal to 1 and z is greater than 0. The method of the invention is particularly suited to the production of layers with thicknesses of the order of nanometers, hundreds of nanometers, several hundred nanometers or even of the order of tens of micrometers, while controlling, as explained above, the oxygen stoichiometry and the Zn/Mn ratio, which is particularly advantageous in electrochemical applications for these crystalline layers of oxides. Thus, in one particular embodiment, said crystalline layer of manganese oxides of composition ZnₓMn_{y}O_{z}, x, y and z being stoichiometric coefficients where x is greater than or equal to 0, and y and z represent stoichiometric coefficients greater than 0; where x is equal to 0, y is greater than or equal to 1, and z is greater than 0; or where x is greater than or equal to 0, y is greater than or equal to 1, and z is greater than 0; or x=1, y=2 and z=4, is obtained according to the above-mentioned method and has a thickness of the order of hundreds of nanometers or even several tens of micrometers. More particularly, said layer is at least 100 nm thick, at least 200 nm thick, at least 300 nm thick, at least 400 nm thick, at least 500 nm thick, at least 600 nm thick, at least 700 nm thick, at least 800 nm thick, at least 900 nm, or even at least 1 μm, or even at least 2 μm thick, or even at least 10 μm micrometers or several tens of micrometers thick. This variability in the thickness of the crystalline layers is obtained in particular by modifying the duration of deposition of the crystalline layer during the method. It can also be obtained by consecutively applying layers one on top of the other.

These layers are particularly suitable for electrochemical applications, as mentioned above. Compared with what is known in the prior art, as shown by the experimental data, the crystalline layers of oxides obtained according to the invention have charging capacities whose values are among the highest known for ZIB battery materials.

A third subject of the invention relates to a cathode for a zinc-ion battery (ZIB) comprising, on a conductive substrate, at least one layer of manganese oxide of formula ZnxMnyOz, x, y and z being stoichiometric coefficients where x is greater than or equal to 0, and y and z represent stoichiometric coefficients greater than 0, and resulting from the method described above in any one of its embodiments. In one particular embodiment, said cathode for a zinc-ion battery (ZIB) comprises, on a conductive substrate, at least one layer of manganese oxides of formula ZnxMnyOz, x, y and z being stoichiometric coefficients where x is greater than or equal to 0, and y represents stoichiometric coefficients greater than or equal to 1 and z represents stoichiometric coefficients greater than 0, and resulting from the method described above in any one of its embodiments.

Characterization of the composition of the at least one oxide layer, and in particular its Zn, Mn and O composition, can be carried out by any means known to a person skilled in the art. In particular, inductively coupled plasma (ICP) spectrometry is particularly suited to the detection of elements in small amounts in the crystalline layers according to the invention.

In one particular embodiment, the cathode according to this third subject of the invention comprises at least one layer of manganese oxides of formula ZnxMnyOz, where x=1, y=2 and z=4.

In another particular embodiment, the conductive substrate comprises a conductive metal selected from Al, Cu, Pt, Ag, alloys such as steel, stainless steel, or an alloy thereof.

As already mentioned, in the cathode according to the third subject of the invention, the conductive substrate may be a conductive polymer or a polymer covered with a layer of conductive material; this layer may take any form, for example sheets or layers.

The absence of annealing to obtain the crystalline layer according to the invention makes it possible to avoid subsequent processing steps for applying the oxide layer to the conductive substrate layer. Thus, the oxides are not in powder form, so the cathode according to this third subject contains no glue or binder. In addition, the resulting crystalline structure is particularly stable and, like the cathodes currently under development, does not require a protective layer to prevent dissolution of the oxide layer in the electrolyte.

A fourth subject of the invention relates to a Zn-ion (ZIB) cell or battery comprising:
at least one cathode as described above in any one of its embodiments,
at least one anode comprising zinc, and
at least one electrolyte of at least one manganese salt

In one particular embodiment, the anode is made of solid zinc. In another particular embodiment, the anode comprises a substrate on which a zinc film is deposited.

The electrochemical performance of these cells or batteries is noteworthy: for example, a charge capacity very close to the initial charge capacity, even after numerous charge and discharge cycles. They can also exhibit charge capacities corresponding to the highest values known in the prior art for ZIB batteries. Thus, the rechargeable batteries according to this fourth subject can be used in many fields, such as optimizing the use of intermittent renewable energies, the use of electric vehicles to limit hydrocarbon emissions, and the use of mobile electronic and electrical devices.

In one particular embodiment, a rechargeable Zn-ion battery (ZIB) according to the fourth subject of the invention achieves a number of charge-discharge cycles greater than or equal to 500, greater than 800, greater than 1000, preferably greater than 1500, preferably greater than 2000, more preferably greater than 2400, more preferably greater than 3000, even more preferably greater than 3500, even more preferably greater than 5000. As demonstrated in the experimental section, the crystalline layers obtained using the method of the invention withstand a particularly large number of charge-discharge cycles without any detectable change in the crystalline structure of the layer.

A fifth subject of the invention relates to a plasma reactor 200 suitable for implementing the method according to the first subject of the invention.

In one particular embodiment, the plasma reactor comprises
a chamber made of silica glass (or “quartz glass”) 201 or any other material allowing the formation and maintenance of an inductive radiofrequency plasma or a microwave plasma via electron cyclotron resonance (ECR),
a radiofrequency electrical source (ideally with an inductive 13.5 MHz frequency) 202,
an induction coil 203 for applying the electromagnetic energy emitted by the source, or alternatively, in cases where the source is a microwave source, an applicator for injecting the energy into the plasma chamber.
a pumping unit 204 and pressure gauge 205 suitable for creating an average vacuum of between 0.1 and 100 mbar in the plasma reactor.
a substrate holder 206 whose temperature can be controlled and regulated.

In this reactor, it will be understood that the electromagnetic energy emitted by the source is applied using the induction coil 203.

The plasma-generating gas is as defined above; in particular, it may be argon, or other gases such as helium or neon. The reactive or plasma-generating gas may also comprise oxygen. As also already mentioned, it is also possible to use other gases, such as CH₄, these gases making it possible in particular to modify the redox character of the plasma medium. It is also possible to use a gas mixture previously prepared with a predefined composition, for example an argon +CH₄ mixture. In one particular embodiment, the reactor 200 is associated with means for controlling the flow rates 209 of the gases used. Thus, in one particular embodiment, the plasma reactor is fitted with flowmeters for controlling the one or more flow rates of the one or more gases used. In one even more particular embodiment, the plasma reactor is associated with mass flowmeters for controlling the one or more flow rates of the one or more gases used.

This reactor comprises two ends, including one through which the reactive gases and precursors are added. This arrangement allows the layer of manganese oxides, which can comprise zinc, to be deposited on the substrate 206 present in the reactor. This also makes it possible to connect the other end to the pumping means 204 arranged to extract by-products such as vapors or gases exiting via the other end, by suction.

In one embodiment, the reactor is associated with at least one device for preparing and adding 207 the liquid or gaseous precursors.

In one particular embodiment, the plasma reactor comprises a plurality of parallel addition paths 208. In particular, these parallel addition paths make it possible to add precursors separately at the same time. They make it possible, by means of consecutive additions, to create layers of homogeneous concentration and thereby form multilayer strata.

Typically, the substrate holder 206 is coupled to means 210 for keeping the substrate and deposition temperature at a predetermined value. Typically 200° C. or less.

Preferably, the chamber is cylindrical in shape and is surrounded by an induction coil 203 made of metal, preferably copper, in order to induce electromagnetic energy in the chamber so as to form and maintain the plasma.

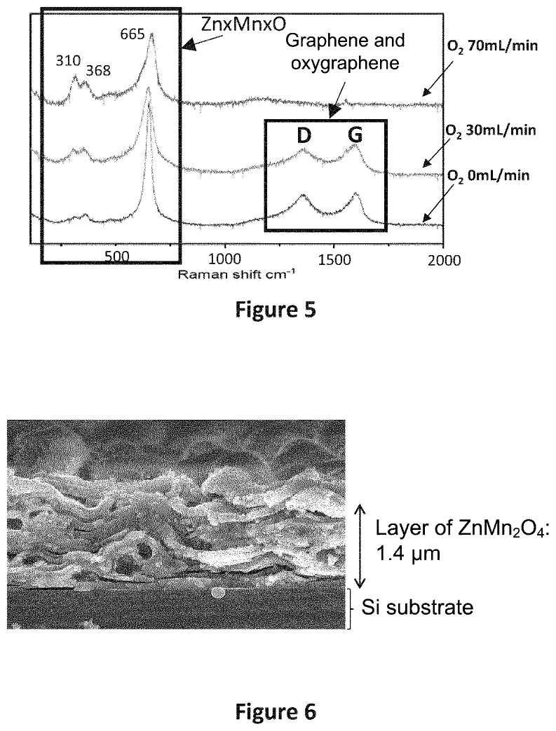

One example of a plasma reactor suitable for implementing the method according to the invention is shown in FIG. 5.

As already mentioned, zinc and manganese precursors, whether inorganic or organic, are added to the chamber of the plasma reactor in the form of nebulizate (i.e. finely divided droplets) in a plasma at advantageously low pressure (e.g. between 0.1 and 100 mbar). The precursor may be in the form of nitrates, chlorides, acetates, acetylacetonate or any other metal salts of zinc or manganese that are soluble in a solvent such as water, ethanol, methanol, propanol, etc.

As also already mentioned, in varying proportions, the plasma-generating gas may be supplemented with oxygen and/or a reducing gas such as CO₂, CH₄, H₂ or any other hydrocarbon. Such mixtures make it possible to control the oxygen stoichiometry of the final deposition of the ZnxMnyOz layer, or even, as shown in FIG. 5, to obtain layers comprising graphene or oxygraphene layers.

Example: electrochemical properties of crystalline layers obtained according to the method according to the invention.

The plasma method according to the invention for producing layers of manganese oxides of formula Znₓ Mn_{y} O_{z} has made it possible to produce layers of the order of one micron in thickness, while controlling the oxygen stoichiometry and the Zn/Mn ratio.

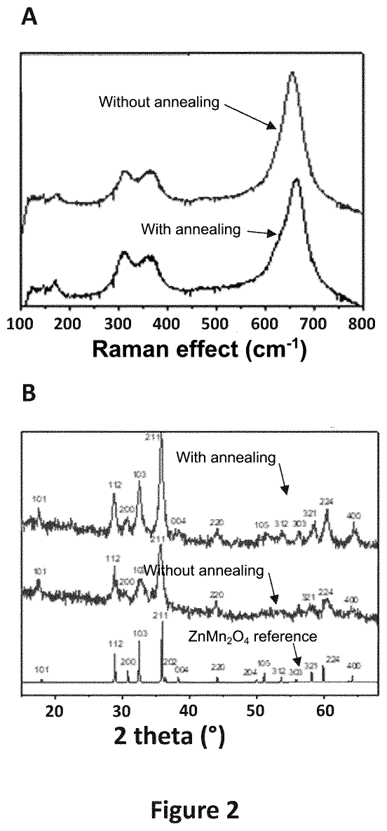

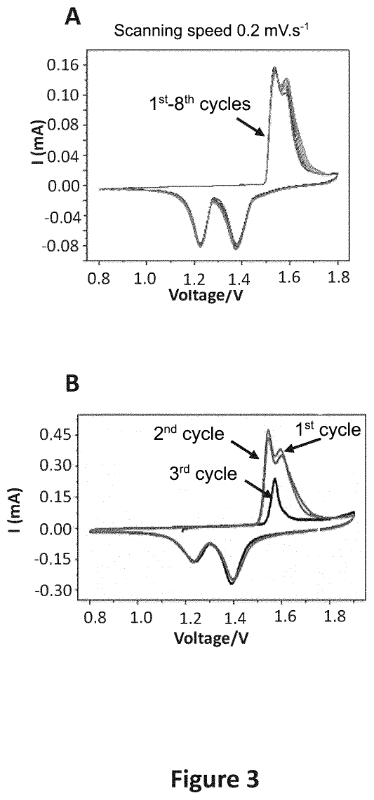

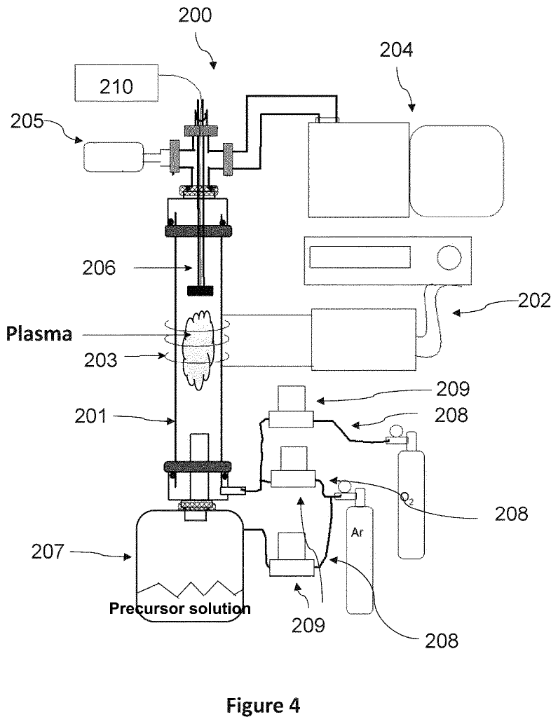

SEM, TEM, XRD and RAMAN analysis of the depositions of the layers produced on the surface of the substrates shows results in line with those found in the literature for substrates produced using conventional methods (e.g. FIG. 2A Raman data, FIG. 2B X-ray diffraction data): The results confirm the crystalline structure of the layers produced at 200° C. according to the method of the invention. In addition, the cyclic voltammetry data shown in FIG. 3A for the layers obtained according to the invention are, for their performance, comparable to those presented in Yang et al (2019). The data presented in FIG. 3A were obtained for a sample of a layer of ZnMn₂O₄ using a solution of composition Zn SO₄+Mn SO₄ as electrolyte. Evaluation of the electrochemical charging and discharging characteristics shows that the layers obtained according to the method of the invention give results comparable to those obtained using methods found in the literature (FIGS. 3A and B).

In addition, it has been observed that the electrochemical performance of the oxide layers obtained according to the method of the invention is quite noteworthy:
the properties are the same at 96% of initial charge capacity after more than 500 charge and discharge cycles.
a charge capacity of the order of 150 mAh/g is obtained, which varies according to the experimental conditions of deposition, in relation to the level of oxygen in the plasma. Values quoted in the literature range from 80 to 180 mAh/g.
after more than 3500 charge cycles, no deterioration in the crystalline layers formed according to the method was observed.

In conclusion, the plasma medium is a reactive gas composed of electrons, radicals, molecules and ionized or excited atoms capable of rapid chemical transformations. The energy required for chemical transformation is supplied by electrons in the molecules, rather than by heat transfer. The plasma medium is made reducing by the in-situ addition or formation of reducing molecules such as carbon monoxide.

Controlling the concentration of oxidizing or reducing species makes it possible to control the oxygen stoichiometry in the depositions of materials in the method of the invention. RAMAN and XRD characterization methods show that the stoichiometry of deposited layers varies with the concentration of oxygen in the plasma-generating gas. This operation of controlling oxygen stoichiometry is one of the special features of this method. As shown in FIG. 5, this controlling of the presence of oxygen also makes it possible to modulate the presence of other structures in the ZnxMnyOz layers of the invention: the higher the oxygen content of the reaction mixture, the fewer graphene layers the layers of manganese oxide contain.

The method of the invention also allows crystalline layers to be produced at temperatures below 200° C. without annealing, whereas layers produced by conventional means require temperatures in excess of 500° C. to obtain crystalline layers.

This method allows layers to be doped with other elements from the periodic table, and doping can be carried out over a wide concentration range. The production of a layer of ZnxMnyOz takes place in a single, relatively short step lasting no more than an hour, depending of course on the desired thickness of the layer to be produced, whereas conventional synthesis methods generally require a large number of time-consuming steps lasting up to several days. FIG. 6 shows an electron microscope image of a 1.4 mm thick layer obtained according to the method of the invention. The depositions can be carried out fully automatically under a controlled atmosphere. The chemical compounds involved in the operations of depositing layers of ZnxMnyOz can be managed in such a way as to have a neutral impact on the environment.

### References

Kexing Cai, Shao-hua, Jun Cong, Kun Li, Sheng-xue Yan, Peng-qing Hou, Qing Wang, Yahui Zhang, Xin Liu and Xuefei Lei, Journal of The Electrochemical Society, Volume 169, Number 3, March 2022.
Mollar M, Tortosa M, Casasús R, Marí B, Electrodepositing ZnxMnyOz alloys from zinc oxide to manganese oxide, Microelectronics Journal 40 (2009) pp 276-279.
Sinian Yang, Manshu Zhang, Xianwen Wu, Xiangsi Wu, Fanghong Zeng, Yuting Li, Shiye Duan, Dihua Fan, Yan Yang, Xianming Wu The excellent electrochemical performances of ZnMn2O4/Mn2O3: The composite cathode material for potential aqueous zinc ion batteries, Journal of Electroanalytical Chemistry 832 (2019) 69-74.
Wu B, Zhang G, Yan M, Xiong T, He P, He L, Xu X, Mai L. Graphene Scroll-Coated α-MnO2 Nanowires as High-Performance Cathode Materials for Aqueous Zn-Ion Battery. Small. 2018 March;14(13):e1703850.

1. A method for synthesizing at least one crystalline layer of manganese oxides that can contain zinc, of formula ZnₓMn_{y}O_{z}, where x is greater than or equal to 0, y is greater than 0, and z is greater than 0,
said method for synthesizing at least one crystalline layer of manganese oxides that can contain zinc being implemented in a chamber of a low-pressure plasma reactor, said pressure in said chamber being kept between 10 Pa and 10⁵, advantageously between 10 Pa and 100 Pa, said method for synthesizing at least one crystalline layer of manganese oxides comprising:
forming a plasma discharge from a plasma-generating gas,
at least one operation of adding, to the chamber of the reactor and in the form of a nebulizate, a predetermined amount of at least one manganese precursor and, optionally, a predetermined amount of at least one additional precursor such as zinc, simultaneously or consecutively,
the precursors being dissolved in a solvent so as to be added to the plasma reactor in the form of a nebulizate,
at least one operation of adding, to the chamber of the reactor, a reactive gas which mixes with the precursor so as to create oxygen vacancy defects in the layer of manganese oxides, and/or so as to maintain a controlled redox environment in the chamber of the reactor,
synthesizing and depositing, on a substrate, the at least one crystalline layer of manganese oxides that can contain zinc, of formula ZnₓMn_{y}O_{z}, at a substrate temperature of 400° C. or less, advantageously 200° C. or less.

2. The method as claimed in claim 1, wherein, to create oxygen vacancy defects in the layer of manganese oxides, at least one carbon precursor such as acetates or acetylacetonates is added.

3. The method as claimed in claim 1, wherein, to create oxygen vacancy defects in the layer of manganese oxides, a predetermined amount of at least one reducing gas is added.

4. The method as claimed in claim 1, wherein the adding step comprises adding zinc precursor in a ratio of amount of manganese precursor/amount of zinc precursor of 2 or greater.

5. (canceled)

6. The method as claimed in claim 1, wherein the adding step further comprises adding a precursor of a doping element comprising salts of: copper and/or vanadium, said precursors being solid under normal temperature and pressure conditions, and added to the reactor dissolved in a solvent in the form of a nebulizate.

7. The method as claimed in claim 1, wherein said synthesizing and depositing operations are carried out at a substrate temperature of 100° C. or less, advantageously less than 50° C.

8. The method as claimed in claim 1, said method being carried out without annealing the at least one crystalline layer of composition ZnₓMn_{y}O_{z}.

9. The method as claimed in claim 1, wherein:
the nebulizates comprising the precursors are carried by the reactive gases or a carrier gas, and in the case of a carrier gas, this is also mixed with the reactive gases;
the reactive gases and the nebulizates are added simultaneously or consecutively through one or more inlet ends of the reactor, and react together in the plasma.

10. (canceled)

11. The method as claimed in claim 1, wherein:
the reactive gas or the plasma-generating gas contains oxygen;
the carrier gas is selected, for example, from the following list: argon, helium, krypton.

12. The method as claimed in claim 1, wherein the at least one reducing gas comprises reducing molecules selected from a hydrocarbon such as an alcohol or an aliphatic hydrocarbon, and/or the at least one reducing gas is selected from carbon monoxide, carbon dioxide, CH₄, H₂, NH₃, methanol, propanol, methane, ethane, propane, or any other hydrocarbon capable of reacting with oxygen in plasma, or mixtures thereof.

13. (canceled)

14. The method as claimed in claim 1, wherein the reactive or plasmagenic gas composition is selected so as to allow the formation of graphene and/or oxygraphene in the at least one crystalline layer of manganese oxides.

15. (canceled)

16. (canceled)

17. The method as claimed in claim 1, wherein, when the precursor mixture contains a manganese salt and a zinc salt, and the percentage of O₂ in the chamber of the reactor:
is equal to 0%, a crystalline layer of manganese oxides only with the following oxide, Mn_{y}O_{z}, is obtained, where x=0, y is greater than or equal to 1 and z is greater than zero,
is greater than 0% and less than 10%, a crystalline layer of manganese oxides comprising the following oxides is obtained: ZnₓMn_{y}O_{z}, where x is greater than 0, y is greater than or equal to 1 and z is greater than zero, Mn_{y}O_{z}, where y is greater than or equal to 1 and z is greater than zero,
is greater than 17%, a crystalline layer of manganese oxides of composition ZnₓMn_{y}O_{z} is obtained.

18. (canceled)

19. The method as claimed in claim 1, wherein the precursors of Mn, optionally of Zn, and of optional doping elements are in the form of nitrate, chloride, acetate, acetylacetonate, acetonate, and/or organometallic compounds of metals such as copper or aluminium or any other salts, and in that the precursors are soluble in a solvent such as water, ethanol, methanol, propanol, hexane, heptane or octane.

20. An assembly comprising at least one crystalline layer of manganese oxides that can contain zinc, of formula ZnₓMn_{y}O_{z}, where x, y and z represent stoichiometric coefficients where x is greater than or equal to 0, y is greater than 0, z is greater than 0, which is obtained according to the method as defined in claim 1, said layer of manganese oxides having a thickness of the order of a nanometer to a thickness of the order of tens of micrometers and having oxygen vacancy defects.

21. The assembly as claimed in claim 20, wherein the layer of manganese oxides ZnₓMn_{y}O_{z} comprises therewithin graphene and/or oxygraphene formed in the at least one crystalline layer of manganese oxides during the plasma synthesis method using a plasma.

22. The assembly as claimed in claim 20, wherein the Zn/Mn ratio is less than 0.5, preferably less than 0.1 and advantageously less than 0.05.

23. The assembly as claimed in claim 20, wherein the manganese oxides of the at least one crystalline layer of manganese oxides are of formula Mn_{y}O_{z}, where y represents stoichiometric coefficients greater than or equal to 1, z represents stoichiometric coefficients greater than 0.

24. The assembly as claimed in claim 20, wherein the manganese oxides of the at least one crystalline layer of manganese oxides are of formula:
ZnxMnyOz, where x and z represent stoichiometric coefficients greater than 0, and y is greater than or equal to 1, and
MnyOz, where y represents stoichiometric coefficients greater than or equal to 1 and z represents stoichiometric coefficients greater than 0.

25. The assembly as claimed in claim 20, comprising:
a crystalline layer composed solely of manganese oxide of formula MnO,
a crystalline layer of manganese oxides wherein the manganese oxides of formula ZnMn₂O₄ and MnO, or
a layer with only the following oxide ZnMn₂O₄.

26. (canceled)

27. (canceled)

28. (canceled)

29. (canceled)

30. (canceled)

31. (canceled)

32. The assembly as claimed in claim 14, intended to form, on a conductive substrate, a cathode for a zinc-ion battery (ZIB).
